(19) United States
(12) Patent Application Publication
(10) Pub. No.: US 2020/0002813 A1
(43) Pub. Date: Jan. 2, 2020

(54) ISOLATED DEPOSITION ZONES FOR ATOMIC LAYER DEPOSITION

(71) Applicant: GLOBALFOUNDRIES Inc., Grand Cayman (KY)

(72) Inventors: Jiehui Shu, Clifton Park, NY (US); John H. Zhang, Altamont, NY (US); Jinping Liu, Ballston Lake, NY (US)

(21) Appl. No.: 16/023,470

(22) Filed: Jun. 29, 2018

(51) Int. Cl. C23C 16/455

(52) U.S. Cl. CPC C23C 16/45551; C23C 16/45565; C23C 16/45519

(57) ABSTRACT

Systems and methods for depositing a material by atomic layer deposition. A first gas distribution unit is configured to provide a first precursor to a first zone inside a reaction chamber. A second gas distribution unit is configured to provide a second precursor to a second zone inside the reaction chamber. A substrate support is arranged to hold the substrates inside the reaction chamber. The substrate support is configured to linearly move the substrates relative to the reaction chamber from the first zone to the second zone as part of a cyclic deposition cycle of an atomic layer deposition process depositing the film on each of the substrates held by the substrate support.

### BACKGROUND

The present invention relates to semiconductor device fabrication and integrated circuits and, more specifically, to systems and methods for depositing a material by atomic layer deposition.

Atomic layer deposition is a technique used to deposit highly uniform and conformal thin films. Atomic layer deposition relies on discrete deposition steps of a deposition cycle to build a thin film on a wafer by sequentially depositing atomic monolayers in each deposition step. A typical process consists of injecting a precursor into a reaction chamber and exposing a wafer for a period of time until a saturated monolayer of reactive precursor molecules is formed by chemisorption on a wafer. The initial precursor is purged from the reaction chamber using an inert gas, followed by injecting a different precursor into the reaction chamber that reacts with the initial monolayer of reactive precursor molecules to form a monolayer of a material on the wafer. After the reaction is complete, the second precursor is purged from the reaction chamber. Cycles of precursor exposure and inert gas purge are iterated to incrementally deposit monolayers of material and build a film having a desired thickness on the wafer.

A single-wafer atomic layer deposition system may be quite slow to reach a thickness target because each deposition cycle deposits only a monolayer of material (e.g., less than 0.1 nm). A furnace-type atomic layer deposition system is configured to batch process multiple wafers, but still lacks adequate throughput to meet certain manufacturing requirements (e.g., thick film applications). By eliminating the inert gas purges, spatial atomic layer deposition systems may achieve a higher throughput than a furnace-type atomic layer deposition system. The process chamber of a spatial atomic layer deposition system is partitioned into multiple process compartments that may be arranged about an axis of rotation. The wafers are held by a susceptor that is rotated about the axis of rotation such that each wafer is sequentially transferred from one process compartment to another compartment for successive exposure to the different precursors in a deposition cycle.

Improved atomic layer deposition systems and methods of depositing a material by atomic layer deposition are needed.

### SUMMARY

In an embodiment of the invention, a method is provided for depositing a layer on each of a plurality of substrates. The method includes holding the substrates on a substrate support inside a reaction chamber, exposing the substrates to a first precursor in a first zone inside the reaction chamber, transporting the substrates on the substrate support in a linear movement from the first zone to a second zone, and exposing the substrates to a second precursor in the second zone inside the reaction chamber.

In an embodiment of the invention, a structure is provided for depositing a film on a plurality of substrates. The deposition system includes a reaction chamber, a first gas distribution unit configured to provide a first precursor to a first zone inside the reaction chamber, a second gas distribution unit configured to provide a second precursor to a second zone inside the reaction chamber, and a substrate support arranged to hold the substrates inside the reaction chamber. The substrate support is configured to linearly move the substrates relative to the reaction chamber from the first zone to the second zone as part of a cyclic deposition cycle of an atomic layer deposition process depositing the film on each of the substrates held by the substrate support.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIG. 1 is a diagrammatic view of a deposition system in accordance with embodiments of the invention.

FIG. 1A is a diagrammatic view of the deposition system of FIG. 1 in which the substrates have been repositioned to a different zone inside the reaction chamber.

FIG. 2 is a diagrammatic view of a deposition system in accordance with alternative embodiments of the invention.

FIG. 3 is a diagrammatic view of a deposition system with multiple process units in accordance with alternative embodiments of the invention.

FIG. 3A is a diagrammatic view of the deposition system of FIG. 3 in which the substrates have been repositioned to a different zone of each process unit.

### DETAILED DESCRIPTION

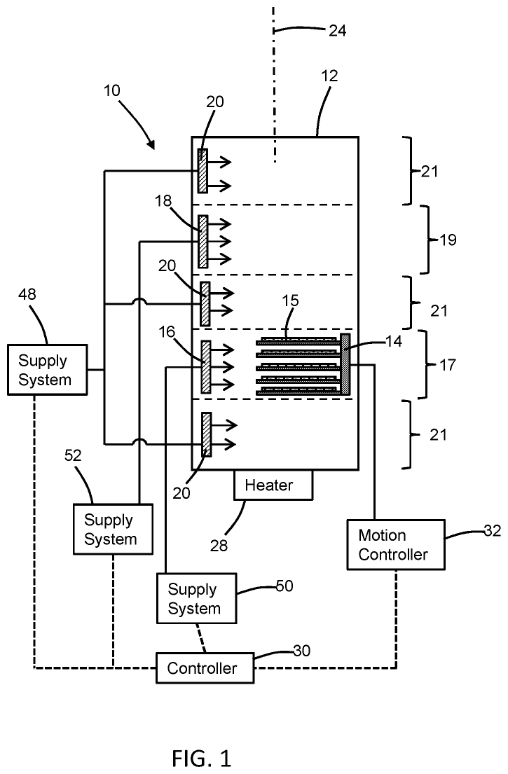

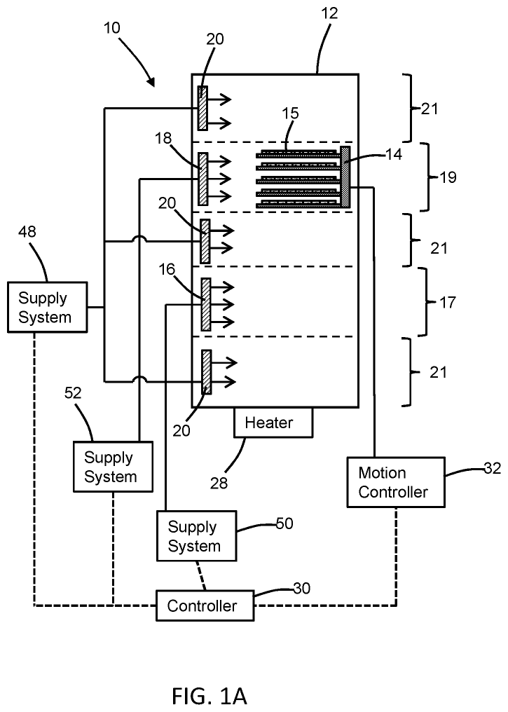

With reference to FIG. 1 and in accordance with embodiments of the invention, a deposition system 10 for processing substrates 15 includes a reaction chamber 12 and a substrate or wafer holder 14 at least partially arranged inside the reaction chamber 12. The deposition system 10, which is shown in a simplified manner, may include additional structures, such as an input/output station that is adapted to receive wafer cassettes, transfer the substrates 15 from the wafer cassettes into the reaction chamber 12, and transfer processed substrates 15 from the reaction chamber 12 back into the wafer cassettes. The deposition system 10 may be configured to process substrates 15 of any size, such as 200 mm wafers, 300 mm wafers, or 450 mm wafers composed of, for example, silicon or a III-V semiconductor.

In the representative embodiment, the reaction chamber 12 of the deposition system 10 has a centerline 24 oriented in a vertical or substantially vertical orientation. In an alternative embodiment, the centerline 24 of the reaction chamber 12 may have a horizontal or substantially horizontal orientation.

The deposition system 10 is equipped with a system controller 30 that is programmed to control and orchestrate the operation of the deposition system 10. The system controller 30 typically includes one or more processing units for controlling various system functions, chamber processes, and support hardware (e.g., detectors, robots, motors, mass flow controllers, etc.), and for monitoring the system and chamber processes (e.g., chamber temperature and pressure, process sequence throughput, chamber process time, etc.). Software instructions and data for instructing the one or more processing units can be coded and stored within a memory and/or storage device. A software program held in memory and executable by the one or more processing units of the system controller 30 determines which tasks are executed on substrates 15, including but not limited to tasks relating to monitoring and execution of chamber processes and other related tasks according to a process recipe providing the deposition of the thin or thick film.

The reaction chamber 12 includes a gas distribution unit 16, a gas distribution unit 18, and multiple gas curtains 20 that are arranged along the height of the reaction chamber 12. In the representative embodiment of a vertical-type system 10, the gas distribution unit 16 introduces a gas or vapor phase precursor into a zone 17 inside the reaction chamber 12, the gas distribution unit 18 introduces a different gas or vapor phase precursor into a zone 17 inside the reaction chamber 12 that is spaced along the height of the reaction chamber 12 from the zone 19, and the gas curtains 20 introduce an inert gas into respective spaced-apart zones 21 inside the reaction chamber 12. For a horizontal-type system 10, the gas distribution units 16, 18 and gas curtains 20 are spaced along the length of the reaction chamber 12, and provide spaced-apart horizontal zones 17, 19, 21 in the horizontally-oriented reaction chamber 12. The gas distribution unit 16 is arranged between a pair of the gas curtains 20 and, similarly, the gas distribution unit 18 is arranged between a pair of the gas curtains 20. One of the gas curtains 20 is arranged between the gas distribution unit 16 and the gas distribution unit 18.

The wafer holder 14 functions as a substrate support holding the substrates 15 inside the reaction chamber 12 in a manner to permit exposure to the gas or vapor phase precursor in each of the respective zones 17, 19. The wafer holder 14, which is connected with the system controller 30, may be configured to collectively move the held substrates 15 vertically upward and vertically downward in linear movements to perform and repeat a deposition cycle that exposes all of the substrates 15 to the gas or vapor phase precursor in zones 17 and 19. Alternatively, in a horizontal-type system 10, the wafer holder 14 may be configured to move the substrates 15 horizontally in opposite back and forth directions with linear movements to perform and repeat a deposition cycle that exposes all of the substrates 15 to zones 17 and 19. The system controller 30 may provide motion instructions to a motion controller 32 that operates, for example, drive motors or pneumatics to provide the linear movements of the wafer holder 14 and substrates 15 held by the wafer holder 14. For example, the wafer holder 14 may be connected by a mechanical linkage with a drive motor that is controlled by instructions from the motion controller 32 to move the portion of the wafer holder 14 physically supporting the substrates 15 linearly relative to the zones 17, 19, 21 inside the reaction chamber 12. The wafer holder 14 may hold multiple substrates 15 inside the reaction chamber 12 that are concurrently processed inside each of the zones 17, 19. For example, the wafer holder 14 may hold a total of five substrates 15.

The reaction chamber 12 may be heated by one or more heating elements 28. For example, the one or more heating elements 28 may be coupled with the wafer holder 14 or with the reaction chamber 12 for indirectly heating the substrates 15. The one or more heating elements 28 may be used to vary the process temperature of the substrates 15 and the ambient environment inside the reaction chamber 12 during deposition in a range from, for example, room temperature to 800° C.

The gas distribution unit 16 and the gas distribution unit 18 may be configured to provide respective gas or vapor phase precursors to the zones 17, 19 that are reacted during multiple deposition cycles to build a thin film or thick film in an atomic layer deposition process. Exemplary precursors that may be supplied to the gas distribution units 16, 18 and from the gas distribution units 16, 18 to the zones 17, 19 include, but are not limited to, dichlorosilane (DCS), hexachlorodisilane (HCD), titanium tetrachloride (TiCl₄), disilane (DIS), ammonia (NH₃), bis(diethylamino)silane (BDEAS), di-iso-propylaminosilane (DIPAS), oxygen (O₂), tris(dimethylamino)silane (3DMAS), TiH₂(NEt₂)₂, etc. The gas curtains 20 may be configured to provide an inert gas (e.g., nitrogen (N₂) or argon (Ar)) to zones 21 that isolate zone 17 and zone 19 from each other, which may prevent cross-contamination between the different zones 17, 19. For example, to form titanium silicide, the gas distribution unit 16 may supply dichlorosilane as a precursor to the zone 17, the gas distribution unit 18 may supply titanium tetrachloride to the zone 19, and the gas curtains 20 may supply nitrogen to the zones 21. The gas distribution units 16, 18 may include an injector, showerhead, etc. that directs one or more streams of the vapor or gas toward the substrates 15 while in the zones 17, 19. The vapor or gas streams may be continuously flowed, or may be controlled to flow only when substrates 15 are positioned within the respective zones 17, 19.

The deposition system 10 includes a supply system 48 coupled by a set of gas lines with the gas curtains 20. During substrate processing, a purge gas may be continuously flowed from the supply system 48 through the gas curtains 20 into the zones 21. The zones 21 provide a gaseous curtain or barrier that prevents, or at the least significantly limits, transfer of the different precursors between the zone 17 and the zone 19. The purge gas also provides an inert atmosphere inside the zones 21 so that deposited and reacted layers carried on the substrates 15 are substantially unchanged when being transported through the zones 21 between the zone 17 and the zone 19.

The deposition system 10 includes a supply system 50 coupled by one or more gas lines with the gas distribution unit 16, and a supply system 52 coupled by one or more gas lines with the gas distribution unit 18. During substrate processing, a precursor may be continuously flowed from the supply system 50 to the gas distribution unit 16 and subsequently into the zone 17 to provide a reactant for a cycle of the atomic layer deposition process, and a different precursor may be continuously flowed from the supply system 52 to the gas distribution unit 18 and subsequently into the zone 19 to provide another reactant for a cycle of the atomic layer deposition process. The supply systems 48, 50, 52, which are connected with the system controller 30, may each include one or more gas or precursor sources, one or more heaters, one or more pressure control devices, one or more mass flow control devices, one or more filters, one or more valves, one or more flow sensors, etc.

The different precursors can originate in a solid phase or a liquid phase that is volatilized to form a vapor phase or a gaseous phase. The different precursors may be delivered to the zones 17, 19 as a gas or vapor, and either with or without the assistance of a carrier gas. The precursor supplied by the supply system 50 to the zone 17 inside the reaction chamber 12 and the precursor supplied by the supply system 52 to the zone 19 inside the reaction chamber 12 are selected in accordance with the composition and characteristics of a material to be deposited as a thin or thick film on each of the substrates. The temperature and pressure of the precursors and the substrates 15 may also be selected, among other variables, according to a process recipe intended to promote film growth.

In use, the reaction chamber 12 of the deposition system 10 may be utilized for depositing a thin or thick film on each of the substrates 15 held by the wafer holder 14. In an initial step of the cyclic deposition process, the wafer holder 14 is operated to place all of the substrates 15 inside the zone 17, and all of the substrates 15 are exposed in the zone 17 to the precursor from supply system 50 that is introduced into the zone 17 as a reactant by the gas distribution unit 16. Precursor flow may be continuous or may be initiated upon entry of the substrates 15 into the zone 17.

During exposure to the vapor or gas phase precursor in zone 17, the wafer holder 14 may be held stationary under the control of the system controller 30 so that the substrates 15 are fixed in position and not in motion. The precursor may be flowed for a given flow time and at a given flow rate into the zone 17, and permitted to adsorb on the exposed surfaces of the substrates 15. For example, the flow rate to zone 17 may range from standard cubic centimeters per minute (sccm) to 10 standard liters per minute (slm), and the flow time may range from 1 second to 30 seconds. The amount of gas or vapor phase precursor that adsorbs on the substrates 15 is dependent, among other deposition conditions, upon the flow rate and flow time as parameters.

In a subsequent step of the deposition cycle and as shown in FIG. 1A, the wafer holder 14 is operated to linearly move the substrates 15 through one of the zones 21 and place all of the substrates 15 inside the zone 19. All of the substrates 15 are exposed in the zone 19 to the precursor from supply system 52 that is introduced into the zone 19 as a reactant by the gas distribution unit 18. The precursor may be flowed for a given flow time and at a given flow rate into the zone 19, and permitted to adsorb on the exposed surfaces of the substrates 15 and react with the existing adsorbed precursor that was previously applied in the zone 17. Precursor flow may be continuous or may be initiated upon entry of the substrates 15 into the zone 19.

During exposure to the precursor in zone 19, the wafer holder 14 may be held stationary under the control of the system controller 30 so that the substrates 15 are fixed in position and not in motion. For example, the flow rate to zone 19 may range from 100 standard cubic centimeters per minute (sccm) to 10 standard liters per minute (slm), and the flow time may range from 1 seconds to 30 seconds. The amount of gas or vapor phase precursor that adsorbs on the substrates 15 and reacts is dependent, among other deposition conditions, upon the flow rate and flow time as parameters, as well as the self-limiting reaction with the initial precursor.

The cyclic process of moving the wafer holder 14 and sequentially exposing the substrates 15 to the different precursors in zone 17 and zone 19 is repeated under the control of the system controller 30 to incrementally increase of the thickness of the deposited material and to eventually deposit a thin or thick film with a given final thickness. For example, the final thickness of the thin or thick film deposited by the atomic layer deposition process on each of the substrates 15 may range from 1 nm to 100 nm. To repeat the deposition cycle, the wafer holder 14 may move the substrates 15 vertically to reposition the substrates 15 inside the zone 17 and expose the substrates 15 to the gas or vapor phase precursor supplied from supply system 50 to initiate another deposition cycle. Alternatively, the wafer holder 14 may be capable of re-positioning the substrates 15 in a different manner that provides vertical circulation to prepare for the subsequent deposition cycle.

A benefit of the deposition system 10 is that the precursor supplied to each of the zones 17, 19 is not varied or changed, and the ambient environments inside the zones 17, 19 are not purged with inert gas in order to change the type of precursor. Another benefit of the deposition system 10 is that the thin or thick film is concurrently formed as an identical or substantially identical coating on each of multiple substrates 15 as determined at least in part by the holding capacity of the wafer holder 14 and/or a number of process units, as subsequently described. The deposition system 10 has some of the properties of a furnace-type atomic layer deposition system that multiple wafers can be batch processed, in combination with some of the properties of a spatial atomic layer deposition system in that the entire reaction chamber 12 does not have to be purged between precursor introductions of the different steps of a deposition cycle. The result of the property combination possessed by the deposition system 10 may be permit increases in processing throughput during an atomic layer deposition process.

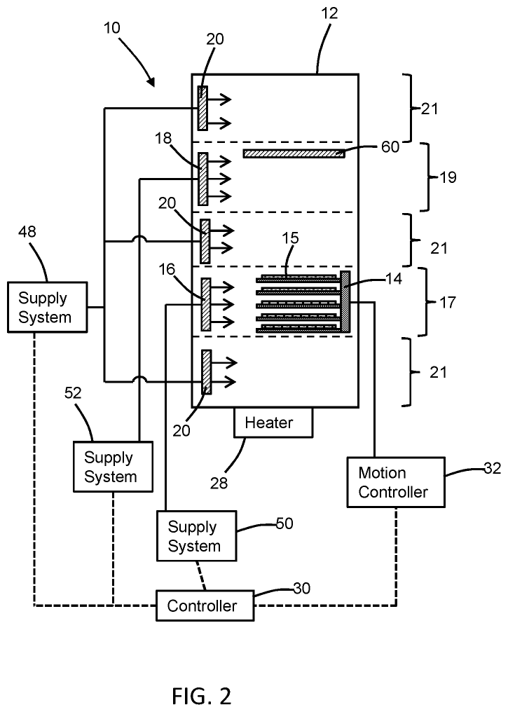

With reference to FIG. 2 in which like reference numerals refer to like features in FIG. 1 and in accordance with an alternative embodiment of the invention, the zone 19 of the reaction chamber 12 may include a plasma source 60 that can generate a plasma containing ions and/or radicals from the gas or vapor precursor supplied by supply system 52. The substrates 15 are exposed to the plasma while in the zone 19. The plasma source 60 may, for example, supply radiofrequency energy that produces the plasma from the precursor in zone 19. The plasma source 60 may be arranged to generate the plasma inside the reaction chamber 12 or, alternatively, may be a remote source that provides the plasma to the reaction chamber 12. With this modification, the deposition system 10 may be used to perform plasma-enhanced atomic layer deposition of thin or thick films on the substrates 15. The zone 17 of the reaction chamber 12 may also include a plasma source (not shown) that can generate a plasma containing ions and/or radicals from the gas or vapor phase precursor supplied by supply system 50.

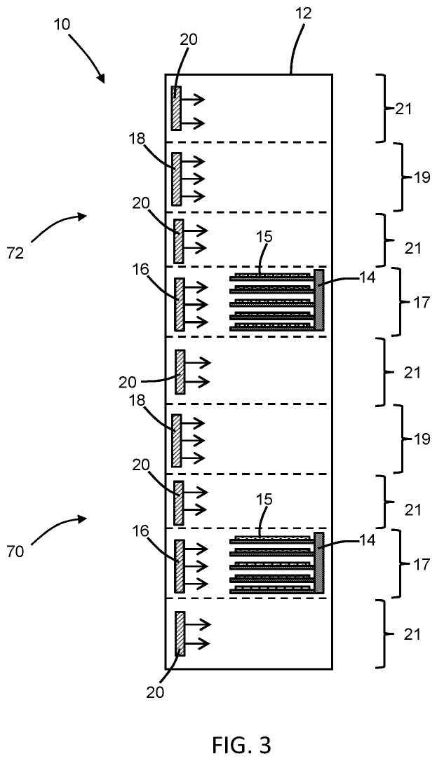

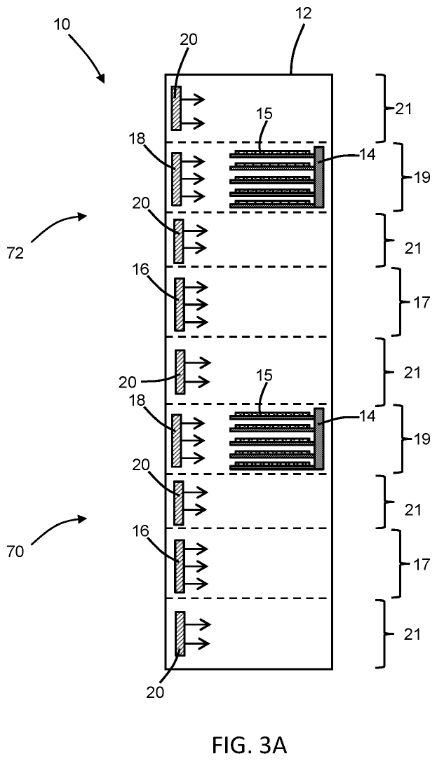

With reference to FIG. 3 in which like reference numerals refer to like features in FIG. 1 and in accordance with an alternative embodiment of the invention, the deposition system 10 may include a set of multiple process units 70, 72 inside the reaction chamber 12 and each of the individual process units 70, 72 may include the zones 17 and 19. One of the zones 21 may be shared among the different process units 70, 72 at the transition between the different process units 70, 72. The multiple process units 70, 72 are stacked to enable the concurrent deposition, within each process unit, of a thin or thick film on multiple substrates 15. Due to stacking, the number of process units 70, 72 may be greater than shown in FIG. 3. For example, the deposition system 10 may include five stacked process units, each of the five processing units may be include the zones 17 and 19, and the wafer holder 14 may support five (5) substrates 15 for performing deposition cycles in each of the process units 70, 72. The ability to stack multiple process units 70, 72 is enabled, at least in part, by the zones 21 providing the curtains of inert gas that separate adjacent pairs of the zones 17, 19 and/or the linear movements substrates 15 between the different zones 17, 19.

During a deposition process, the substrates 15 within each process unit 70, 72 may be all be positioned in the same one of the zones 17, 19 at any given time. For example, the substrates 15 within each process unit 70, 72 may be all be positioned in zone 17 during a portion of a deposition cycle, the substrates 15 within each process unit 70, 72 may be concurrently transferred to zone 19, as shown in FIG. 3A, of one of the process units 70, 72, and the substrates 15 within each process unit 70, 72 may be all be positioned in zone 19 during the successive portion of the deposition cycle.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, etc. are made by way of example, and not by way of limitation, to establish a frame of reference. The terms “vertical” and “normal” refer to a direction perpendicular to a horizontal plane. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A deposition system for depositing a film on a plurality of substrates, the deposition system comprising:
a reaction chamber;
a first gas distribution unit configured to provide a first precursor to a first zone inside the reaction chamber;
a second gas distribution unit configured to provide a second precursor to a second zone inside the reaction chamber; and
a substrate support configured to hold the substrates inside the reaction chamber, the substrate support arranged to linearly move the substrates relative to the reaction chamber from the first zone to the second zone as part of a cyclic deposition cycle of an atomic layer deposition process depositing the film on each of the substrates held by the substrate support.

2. The deposition system of claim 1 further comprising:
one or more heating elements configured to heat the substrates held by the substrate support.

3. The deposition system of claim 1 further comprising:
a gas curtain configured to provide an inert gas to a third zone inside the reaction chamber, the third zone arranged between the first zone and the second zone for isolating the first zone from the second zone.

4. The deposition system of claim 3 wherein the substrate support is arranged relative to the first zone, the second zone, and the third zone to move the substrates through the third zone when moving between the first zone and the second zone.

5. The deposition system of claim 4 wherein the substrate support is configured to move substrates in a vertical direction through the third zone when moving between the first zone and the second zone.

6. The deposition system of claim 1 wherein the reaction chamber has a centerline that is oriented substantially vertically, and the first gas distribution unit and the second gas distribution unit are arranged along the centerline.

7. The deposition system of claim 1 further comprising:
a third gas distribution unit configured to provide the first precursor to a third zone inside the reaction chamber; and
a fourth gas distribution unit configured to provide the second precursor to a fourth zone inside the reaction chamber.

8. The deposition system of claim 7 wherein the third gas distribution unit and the fourth gas distribution unit are stacked with the first gas distribution unit and the second gas distribution unit.

9. The deposition system of claim 7 further comprising:
a first gas curtain configured to provide an inert gas to a fifth zone inside the reaction chamber, the fifth zone arranged between the second zone and the third zone for isolating the third zone from the second zone.

10. The deposition system of claim 9 further comprising:
a second gas curtain configured to provide an inert gas to a sixth zone inside the reaction chamber, the sixth zone arranged between the first zone and the second zone for isolating the first zone from the second zone or between the third zone and the fourth zone for isolating the third zone from the fourth zone.

11. The deposition system of claim 1 wherein the first gas distribution unit is configured as a plasma source generating a plasma in the first zone from the first precursor.

12. The deposition system of claim 1 further comprising:
a controller configured to cause the substrate support to linearly move the substrates relative to the reaction chamber from the first zone to the second zone as part of the cyclic deposition cycle of the atomic layer deposition process,
wherein the controller is further configured to hold the substrate support and the substrates stationary while the substrates are exposed to the first precursor in the first zone and while the substrates are exposed to the second precursor in the second zone.

13. A method for depositing a layer on each of a plurality of substrates, the method comprising:
holding the substrates on a substrate support inside a reaction chamber;
exposing the substrates to a first precursor in a first zone inside the reaction chamber;
transporting the substrates on the substrate support in a linear movement from the first zone to a second zone; and
exposing the substrates to a second precursor in the second zone inside the reaction chamber.

14. The method of claim 13 further comprising:
supplying an inert gas to a third zone inside the reaction chamber that is arranged between the first zone and the second zone for isolating the first zone from the second zone.

15. The method of claim 14 wherein the substrate support is arranged relative to the first zone, the second zone, and the third zone to move the substrates through the third zone when moving between the first zone and the second zone.

16. The method of claim 15 wherein the substrate support moves substrates in a vertical direction through the third zone when moving between the first zone and the second zone.

17. The method of claim 13 wherein the reaction chamber has a centerline that is oriented substantially vertically, and the first zone and the second zone are arranged along the centerline.

18. The method of claim 13 wherein exposing the substrates to the second precursor in the second zone inside the reaction chamber comprises:
generating a plasma in the first zone from the first precursor.

19. The method of claim 13 further comprising:
holding the substrate support and the substrates stationary while the substrates are exposed to the first precursor in the first zone and while the substrates are exposed to the second precursor in the second zone.

20. The method of claim 13 further comprising:
providing the first precursor to a third zone inside the reaction chamber; and
supplying an inert gas to a fourth zone inside the reaction chamber that is arranged between the second zone and the third zone for isolating the second zone from the third zone.
